(19) United States
(12) Patent Application Publication
(10) Pub. No.: US 2025/0337396 A1
(43) Pub. Date: Oct. 30, 2025

(54) THERMAL SENSOR BASED ON OSCILLATION OF RING OSCILLATOR

(71) Applicant: MEDIATEK INC., Hsinchu City (TW)

(72) Inventors: Chin-Kai LAI, Hsinchu City (TW); Kuan-Ta CHEN, Hsinchu City (TW)

(21) Appl. No.: 19/260,768

(22) Filed: Jul. 7, 2025

Related U.S. Application Data
(63) Continuation-in-part of application No. 18/741,134, filed on Jun. 12, 2024.
(60) Provisional application No. 63/508,941, filed on Jun. 19, 2023.

(51) Int. Cl. H03K 3/03; G01K 7/16

(52) U.S. Cl. CPC H03K 3/0315; G01K 7/16

(57) ABSTRACT

A thermal sensor using a ring oscillator is shown. The ring oscillator oscillates based on a resistance-and-capacitance (RC) coefficient. The ring oscillator includes a temperature-sensitive resistance circuit. The resistance factor of the resistance-and-capacitance coefficient depends on the temperature-sensitive resistance circuit. The thermal sensor evaluates temperature information, T, based on the oscillation of the ring oscillator.

### CROSS REFERENCE TO RELATED APPLICATIONS

This application is a Continuation-In-Part of pending U.S. patent application Ser. No. 18/741,134 filed Jun. 12, 2024 and entitled “Ring Oscillator with an overstress solution”, which claims the benefit of provisional Application No. 63/508,941, filed June 19, 2023, the entirety of which is incorporated by reference herein.

### BACKGROUND OF THE INVENTION

### Field of the Invention

The present invention relates to a thermal sensing technology implemented based on a ring oscillator.

### Description of the Related Art

Thermal sensors are used to measure temperature in various devices and systems. Today, electronic products may be used in extreme climates. Electronic products may need to switch between different operating modes to better handle the different temperatures. A reliable on-chip thermal sensor is called for.

### BRIEF SUMMARY OF THE INVENTION

A reliable thermal sensor is presented in the disclosure.

A thermal sensor in accordance with an exemplary embodiment of the disclosure includes a ring oscillator. The ring oscillator oscillates based on a resistance-and-capacitance (RC) coefficient. The ring oscillator includes a temperature-sensitive resistance circuit, and the resistance factor of the RC coefficient depends on the temperature-sensitive resistance circuit. The thermal sensor evaluates temperature information, T, based on the oscillation of the ring oscillator.

The thermal sensor may be implemented on a system on a chip (SoC) to sense the environmental temperature for the electronic product.

In an exemplary embodiment, the ring oscillator has a critical node, and a first capacitor coupled between an input node of a final-stage oscillation unit of the ring oscillator and the critical node. The ring oscillator further has a second capacitor coupled between the critical node and ground. To solve the overstress problem, an oscillation structure is proposed. The temperature-sensitive resistance circuit is coupled between the output node of the final-stage oscillation unit and the critical node.

In an exemplary embodiment, the temperature-sensitive resistance circuit has a proportional-to-absolute-temperature resistor, which corresponds to a positive temperature coefficient.

In an exemplary embodiment, the temperature-sensitive resistance circuit further has a complementary-to-absolute-temperature resistor which corresponds to a negative temperature coefficient, and is operative to remove higher-order non-ideal factors from the evaluated result of the temperature information, T.

In an exemplary embodiment, the thermal sensor further has a computing module, operative to switch the temperature-sensitive resistance circuit between a first mode and a second mode. In the first mode, the proportional-to-absolute-temperature resistor is enabled, the complementary-to-absolute-temperature resistor is disabled, and a first oscillation period, Period_{PTAT}, of the ring oscillator is obtained. In the second mode, the complementary-to-absolute-temperature resistor is enabled, the proportional-to-absolute-temperature resistor is disabled, and a second oscillation period, Period_{CTAT}, of the ring oscillator is obtained. The computing module evaluates the temperature information, T, based on a divided value, Period_{PTAT}/Period_{CTAT}, which results in an enhanced temperature coefficient, T_{enhanced}. The linearity of the thermal sensor is also improved.

In an exemplary embodiment, the computing module generates a digital code, D, to represent the temperature information, T, where,

$$D = \frac{{Peiord}_{PT AT}}{{Peiord}_{CT AT}} \times {2}^{14}$$

In an exemplary embodiment, the computing module calculates the enhanced temperature coefficient, TC_{enhanced}, based on Period_{PTAT}/Period_{CTAT} obtained in several temperatures, and transforms the digital code, D, to the temperature information, T, based on the enhanced temperature coefficient, TC_{enhanced}.

In an exemplary embodiment, three divided values,

$$\frac{{Peiord}_{PT AT}}{{Peiord}_{CT AT}} @ 125 ° C . , \frac{{Peiord}_{PT AT}}{{Peiord}_{CT AT}} @ - 40 ° C . , and \frac{{Peiord}_{PT AT}}{{Peiord}_{CT AT}} @ 30 ° C . ,$$

are obtained at three different temperatures, 125° C., −40°° C., and 30° C. The computing module calculates the enhanced temperature coefficient, TC_{enhanced}, by performing the following calculation:

$${TC}_{enhanced} = \frac{\frac{{Peiord}_{PT AT}}{{Peiord}_{CT AT}} \times {2}^{14} @ 125 ° C . - \frac{{Peiord}_{PT AT}}{{Peiord}_{CT AT}} \times {2}^{14} @ - 40 ° C .}{\frac{{Peiord}_{PT AT}}{{Peiord}_{CT AT}} \times {2}^{14} @ 30 ° C . \times ( 125 - ( - 40 ) )}$$

In an exemplary embodiment, the computing module evaluates the temperature information, T, by performing the following calculation:

$$T = 30 + \frac{1}{T {C}_{enhanced}} \times ( \frac{D}{D @ 30 ° C .} - 1 )$$

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 illustrates a thermal sensor 100 in accordance with an exemplary embodiment of the disclosure, which includes a ring oscillator 102 oscillating based on a resistance-and-capacitance (RC) coefficient, and a computing module 104 operating the ring oscillator 102 for temperature sensing;

FIG. 2A and FIG. 2B illustrate a ring oscillator 200 with an RC coefficient in accordance with an exemplary embodiment, which includes a temperature-sensitive resistance circuit 202 that determines the resistance factor of the RC coefficient and is switched between two modes;

FIG. 3A to FIG. 3E show the other ring oscillation structures which also solve the overstress problem and are applied to implement the disclosed thermal sensor; and

FIG. 4 is a flow chart illustrating a thermal sensing method in accordance with an exemplary embodiment of the disclosure;

FIG. 5A and FIG. 5B depict a ring oscillator 500 using another temperature-sensitive resistance circuit 502 in accordance with an exemplary embodiment of the disclosure; and

FIG. 6A and FIG. 6B show an example of the demultiplexer 504 in accordance with an exemplary embodiment of the disclosure.

### DETAILED DESCRIPTION OF THE INVENTION

The following description enumerates various embodiments of the disclosure, but is not intended to be limited thereto. The actual scope of the disclosure should be defined according to the claims. The various blocks and modules mentioned below may be implemented by a combination of hardware, software, and firmware, and may also be implemented by special circuits. The various blocks and modules are not limited to being implemented separately, but can also be combined together to share certain functions.

A ring oscillator is implemented by a plurality of oscillation units which are connected in a ring. An oscillation unit may be an inverter, a NAND gate, and so on. In this disclosure, the ring oscillator is used to implement a thermal sensor.

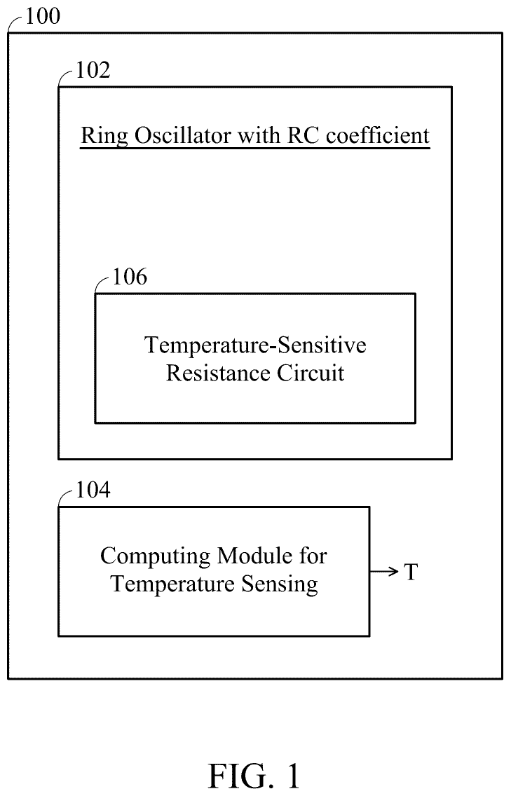

FIG. 1 illustrates a thermal sensor 100 in accordance with an exemplary embodiment of the disclosure, which includes a ring oscillator 102 oscillating based on a resistance-and-capacitance (RC) coefficient, and a computing module 104 operating the ring oscillator 102 for temperature sensing. The oscillation period (P) of the ring oscillator 102 depends on a resistance factor (R) and a capacitance factor (C). The ring oscillator 102 uses a temperature-sensitive resistance circuit 106 to implement the resistance factor (R). Thus, the temperature information (T) of the environment is presented in the oscillation period (P) of the ring oscillator 102, and a thermal sensor 100 is implemented. The computing module 104 may operate the ring oscillator 102 to evaluate the temperature information (T) based on the oscillation of the ring oscillator 102.

In some exemplary embodiments, the thermal sensor is implemented on a system on a chip (SoC), and the computing module 104 is implemented by a finite state machine (FSM) in the SoC. According to the finite state machine (FSM), the ring oscillator 102 operates, and the oscillation of the ring oscillator 102 is monitored and used in the evaluation of the temperature information (T).

In an exemplary embodiment, to improve the thermal sensing sensitivity, the temperature-sensitive resistance circuit 106 is specially designed to enhance the temperature coefficient (TC) and the linearity of the thermal sensor. The details will be described later.

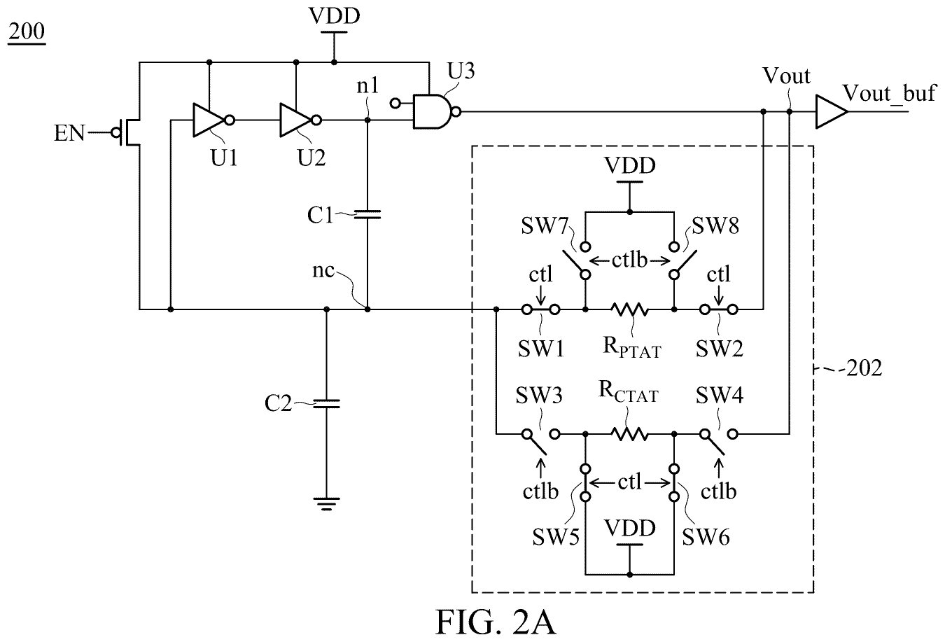

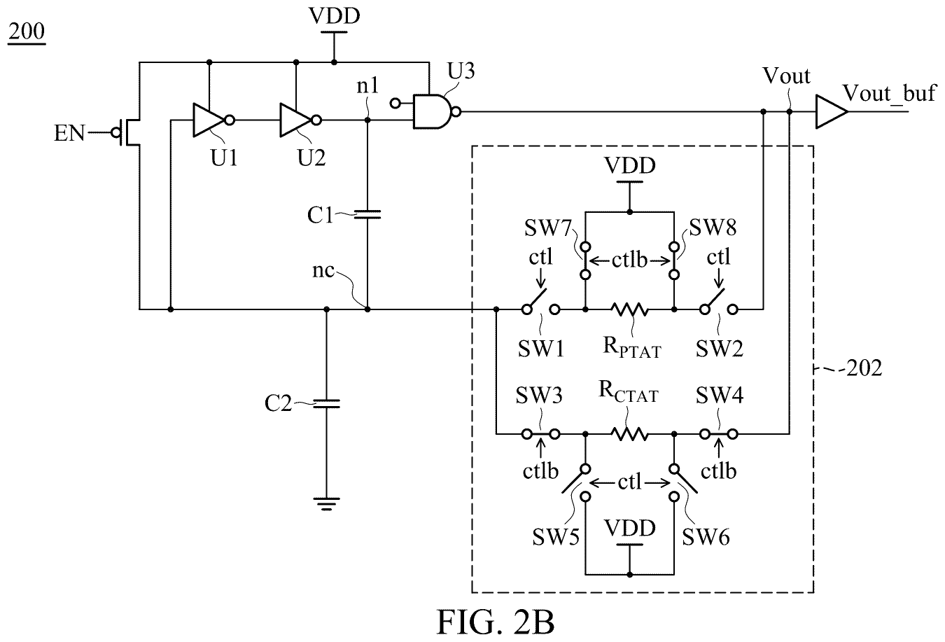

FIG. 2A and FIG. 2B illustrate a ring oscillator 200 with an RC coefficient in accordance with an exemplary embodiment, which includes a temperature-sensitive resistance circuit 202 that determines the resistance factor of the RC coefficient and is switched between two modes. The temperature-sensitive resistance circuit 202 includes a proportional-to-absolute-temperature resistor R_{PTAT} and a complementary-to-absolute-temperature resistor R_{CTAT}.

The proportional-to-absolute-temperature resistor R_{PTAT} corresponds to a positive temperature coefficient (TC_{PTAT}>0, which means R_{PTAT}∝T), and is enabled in a first mode (rm mode) as presented in FIG. 2A. In the first mode (rm mode), the switches SW1 and SW2 are closed by the control signal ctl to equip the proportional-to-absolute-temperature resistor R_{PTAT} to the ring oscillator 200, and the switches SW3 and SW4 are opened by the inverse control signal ctlb to disconnect the complementary-to-absolute-temperature resistor R_{CTAT} from the ring oscillator 200. In the disabled status, the two ends of the complementary-to-absolute-temperature resistor R_{CTAT} are coupled to the power terminal VDD of the ring oscillator 200 (rather than being floating) through the closed switches SW5 and SW6. In this way, two ends of the disabled R_{CTAT} are biased at the same voltage level VDD, and leakages through disabled R_{CTAT} are suppressed. The switches SW7 and SW8 are opened by the inverse control signal ctlb to correspond to the proportional-to-absolute-temperature resistor R_{PTAT} enabled by the control signal ctl.

As for the complementary-to-absolute-temperature resistor R_{CTAT}, it corresponds to a negative temperature coefficient (TC_{CTAT}<0, which means R_{CTAT}∝1/T), and is enabled in a second mode (rhr mode) as presented in FIG. 2B. In the second mode (rhr mode), the switches SW1 and SW2 are opened by the control signal ctl to disconnect the proportional-to-absolute-temperature resistor R_{PTAT} from the ring oscillator 200, and the switches SW3 and SW4 are closed by the inverse control signal ctlb to equip the complementary-to-absolute-temperature resistor R_{CTAT} to the ring oscillator 200. In the enabled status, the two ends of the complementary-to-absolute-temperature resistor R_{CTAT} are disconnected from the power supply voltage VDD by using the control signal ctl to open the switches SW5 and SW6. The switches SW7 and SW8 are closed by the inverse control signal ctlb to correspond to the proportional-to-absolute-temperature resistor R_{PTAT} disabled by the control signal ctl. In this way, the leakages through the disabled R_{PTAT} are suppressed.

The computing module 104 operates the temperature-sensitive resistance circuit 202 to switch between the first mode (rm mode) and the second mode (rhr mode). In the first mode (rm mode), an oscillation period Period_{PTAT} of the ring oscillator 200 (e.g., evaluated from the output signal Vout or Vout_buf) is obtained, which depends on the positive temperature coefficient TC_{PTAT}. In the second mode (rhr mode), an oscillation period Period_{CTAT} of the ring oscillator 200 is obtained, which depends on the negative temperature coefficient TC_{PTAT} TC_{CTAT}. In this disclosure, the oscillation period Period_{PTAT} is divided by the oscillation period Period_{CTAT} to eliminate the non-ideal higher-order factors from the evaluated result of the temperature information (T). And, in this way, an enhanced temperature coefficient TC_{enhanced} is obtained. For example, if TC_{PTAT} is 1165 ppm/° C., and TC_{CTAT} is −340 ppm/° C., by the divided calculation, Period_{PTAT}/Period_{CTAT}, an enhanced temperature coefficient TC_{enhanced} 1520 ppm/° C. may be generated. A high linearity thermal sensor with the enhanced temperature coefficient TC_{enhanced} is proposed in the disclosure.

In an exemplary embodiment, the computing module evaluates the temperature information, T, based on a divided value, Period_{PTAT}/Period_{CTAT}.

In an exemplary embodiment, the computing module 104 generates a digital code, D, to represent the temperature information, T, where,

$$D = \frac{{Peiord}_{PT AT}}{{Peiord}_{CT AT}} \times {2}^{14}$$

In an exemplary embodiment, the computing module 104 calculates the enhanced temperature coefficient, TC_{enhanced}, based on Period_{PTAT}/Period_{CTAT} obtained in several temperatures, and transforms the digital code, D, to the temperature information, T, based on the enhanced temperature coefficient, TC_{enhanced}.

In an exemplary embodiment, three divided values,

$$\frac{{Peiord}_{PT AT}}{{Peiord}_{CT AT}} @ 125 ° C . , \frac{{Peiord}_{PT AT}}{{Peiord}_{CT AT}} @ - 40 ° C . , and \frac{{Peiord}_{PT AT}}{{Peiord}_{CT AT}} @ 30 ° C . ,$$

are obtained at three different temperatures, 125° C., −40° C., and 30° C., which corresponds to the extreme hot temperature, the extreme cold temperature, and the normal temperature, respectively. The computing module 104 may calculate the enhanced temperature coefficient, TC_{enhanced}, by performing the following calculation:

$${TC}_{enhanced} = \frac{\frac{{Peiord}_{PT AT}}{{Peiord}_{CT AT}} \times {2}^{14} @ 125 ° C . - \frac{{Peiord}_{PT AT}}{{Peiord}_{CT AT}} \times {2}^{14} @ - 40 ° C .}{\frac{{Peiord}_{PT AT}}{{Peiord}_{CT AT}} \times {2}^{14} @ 30 ° C . \times ( 125 - ( - 40 ) )}$$

In an exemplary embodiment, the normal temperature (30° C.) of the environment is also considered in transforming the digital code (D) to the temperature information (T). For example, the computing module 104 may evaluate the temperature information (T) by performing the following calculation:

$$T = 30 + \frac{1}{T {C}_{enhanced}} \times ( \frac{D}{D @ 30 ° C .} - 1 )$$

The reference temperatures 125° C., −40° C., and 30° C. may be substituted by the other values. It is not intended to limit the reference temperatures for calculating the enhanced temperature coefficient TC_{enhanced} and the digital code D to the aforementioned values 125° C., −40° C., and 30° C. The calculations may be also modified. For example, the power of 2 is not limited to 14. It depends on the calculation precision of the computing module 104. The main concept is the calculation of Period_{PTAT}/Period_{CTAT}, which results in the enhanced temperature coefficient TC_{enhanced} and improves the linearity of the thermal sensor.

In some other exemplary embodiments, the complementary-to-absolute-temperature resistor R_{CTAT} is replaced by a temperature-insensitive resistor, e.g., with a temperature coefficient 0, or greater than 0 but smaller than a threshold.

Especially, the ring oscillator 200 is in an overstress removed design. The oscillation swing is controlled within the proper range (GND˜VDD) by the voltage divider formed by the capacitors C1 and C2. Referring to the capacitors C1 and C2 which are connected in series between an input node n1 of the final-stage oscillation unit U3 and the ground, the voltage change that the capacitor C1 couples to the critical node nc is effectively suppressed. The oscillation at any node of the ring oscillator 200, therefore, is controlled within GND˜VDD. The overstress problem of a conventional ring oscillator is solved. A reliable oscillation signal Vout/Vout_Buf is generated. Based on the reliable oscillation, the evaluated temperature information (T) is also reliable. The temperature-sensitive resistance circuit 202 is coupled between the critical node nc and an output node (Vout) of the final-stage oscillation unit U3.

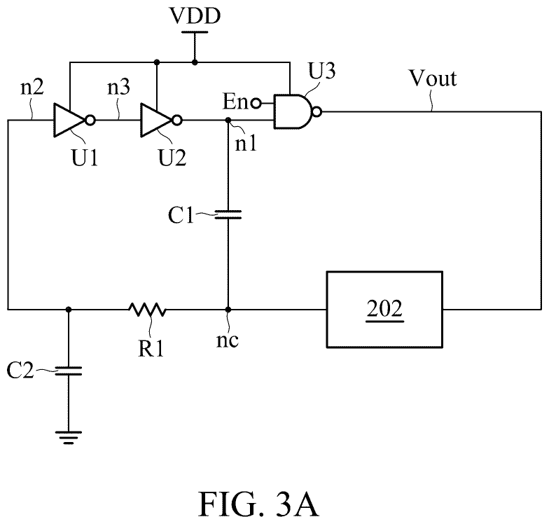

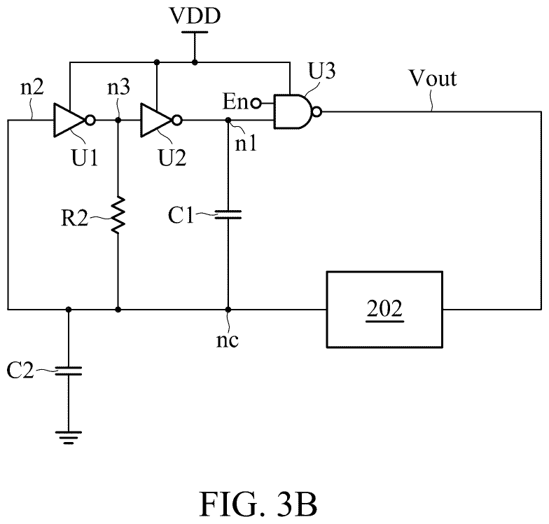

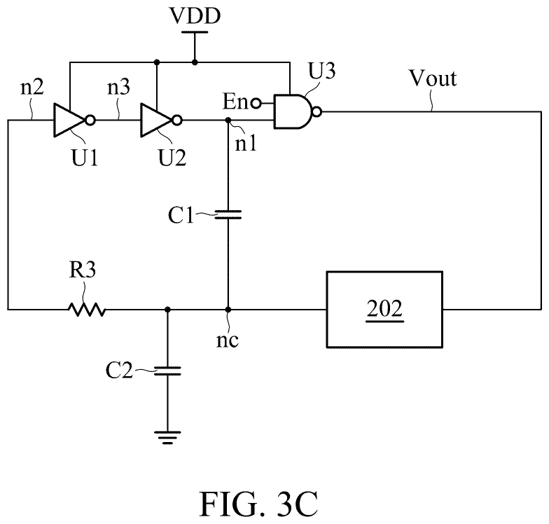

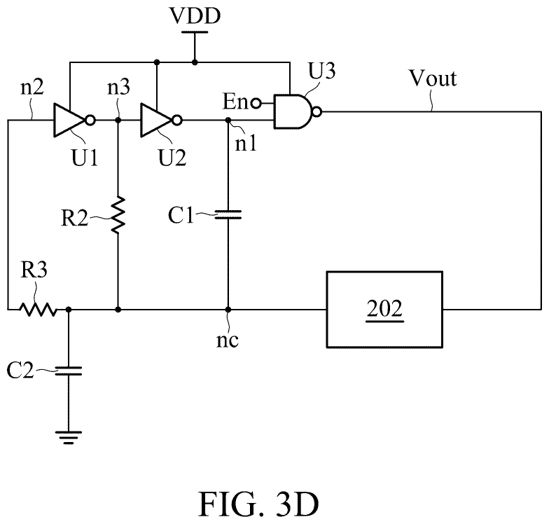

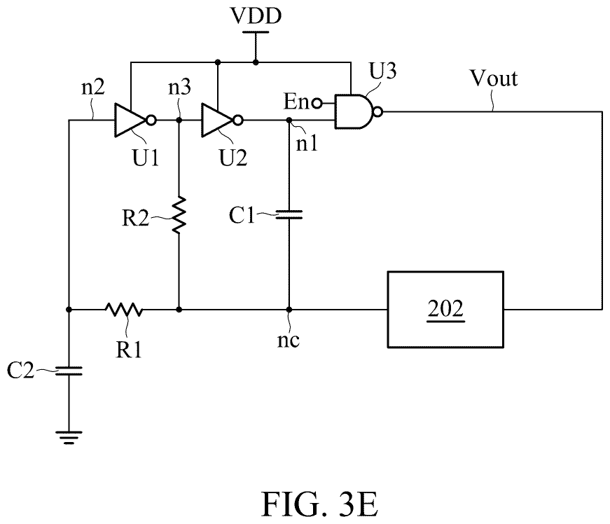

In FIG. 2A and FIG. 2B, the capacitor C2 is directly connected to the critical node nc. The critical node nc is an input node of a first-stage oscillation unit U1 of the ring oscillator 200. However, the solution for overstress may be implemented in many ways. FIG. 3A to FIG. 3E show the other ring oscillation structures which also solve the overstress problem and are applied to implement the disclosed thermal sensor.

In FIG. 3A, a resistor R1 is coupled between the critical node nc and the input node n2 of the first-stage oscillation unit U1, and the capacitor C2 is coupled to the critical node nc through the resistor R1.

In FIG. 3B, the ring oscillator has a resistor R2 coupled between the critical node nc and an intermediate node n3 between two oscillation units U1 and U2 in front of the final-stage oscillation unit U3 in the ring oscillator. In another example, there may be more than three stages of oscillation units in the ring oscillator, and the intermediate node may be a connection node between any two intermediate stages of oscillation units in the ring oscillator.

In FIG. 3C, the ring oscillator has a resistor R3 coupled between the critical node nc and the input node n2 of the first-stage oscillation unit U1. The capacitor C2 is coupled to the input node n2 of the first-stage oscillation unit U1 through the resistor R3.

FIG. 3D includes the resistor R2 as well as the resistor R3. FIG. 3E includes the resistor R1 as well as the resistor R2.

In the various oscillation structures shown in FIG. 3A˜FIG. 3E, the temperature-sensitive resistance circuit 202 is also coupled between the critical node nc and the output node (Vout) of the final-stage oscillation unit U3. The thermal sensors using the ring oscillators presented in FIG. 3A to 3E are all reliable.

The oscillation units U1˜U3 may be replaced by the other kinds of electronic components. For example, the oscillation unit U3 is not limited to a NAND gate, and may be replaced by an inverter. Furthermore, the oscillation structure may be implemented by the other number of oscillation units (e.g., an oscillation structure including two oscillation units in a ring, or an oscillation structure including four or more oscillation units in a ring).

In some other exemplary embodiments, the temperature-sensitive resistance circuit 202 is replaced to contain just the proportional-to-absolute-temperature resistor R_{PTAT} (TC_{PTAT}>0, i.e. R_{PTAT}∝T), without using another resistor for the second mode). The temperature information, T, is evaluated from the oscillation period Period_{PTAT} rather than the divided value of Period_{PTAT}/Period_{CTAT}.

Any ring oscillator using the capacitors C1 and C2 to solve the overstress problem and including a temperature-sensitive resistance circuit (just one proportional-to-absolute-temperature resistor R_{PTAT}, or using the two modes circuit 202) should be considered within the scope of the disclosure.

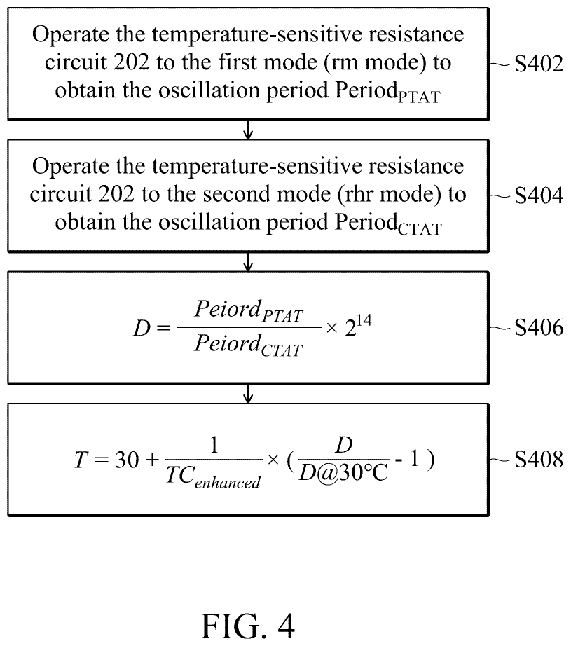

FIG. 4 is a flow chart illustrating a thermal sensing method in accordance with an exemplary embodiment of the disclosure.

In step S402, the computing module 104 switches the temperature-sensitive resistance circuit 202 to the first mode (rm mode) to obtain the oscillation period Period_{PTAT}. In step S404, the computing module 104 switches the temperature-sensitive resistance circuit 202 to the second mode (rhr mode) to obtain the oscillation period Period_{CTAT}. In step S406, the computing module 104 calculates the digital code (D) by performing the following calculation:

$$D = \frac{{Peiord}_{PT AT}}{{Peiord}_{CT AT}} \times {2}^{14}$$

In step S408, the computing module 104 evaluates the temperature information (T) by performing the following calculation:

$$T = 30 + \frac{1}{T {C}_{enhanced}} \times ( \frac{D}{D @ 30 ° C .} - 1 )$$

For the better power efficiency, the switches provided to change the mode of the temperature-sensitive resistance circuit 202 may be replaced by a logic circuit, wherein the logic circuit successfully breaks the leakage path between the resistors R_{PTAT}/R_{CTAT} and the output terminal Vout.

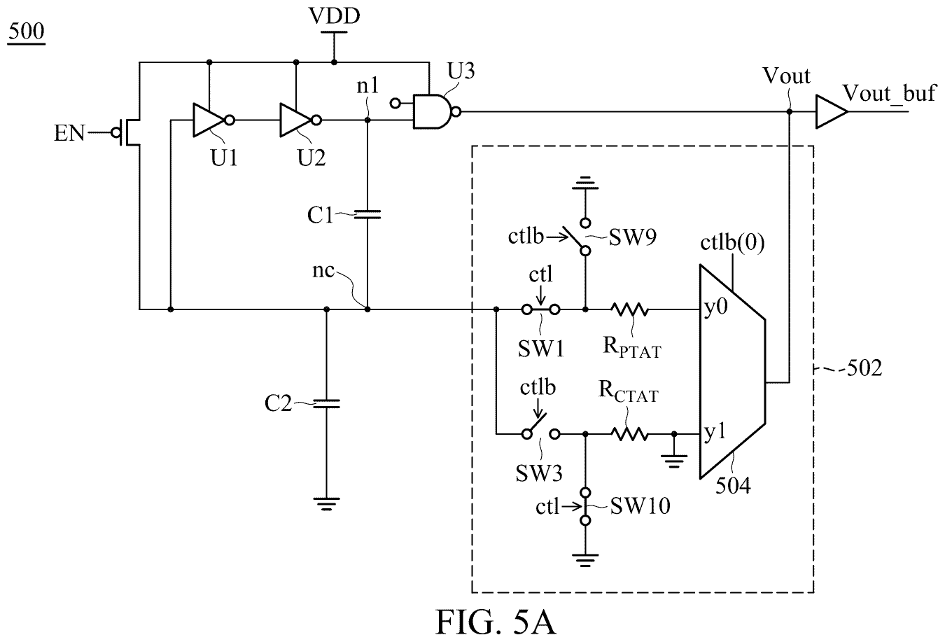

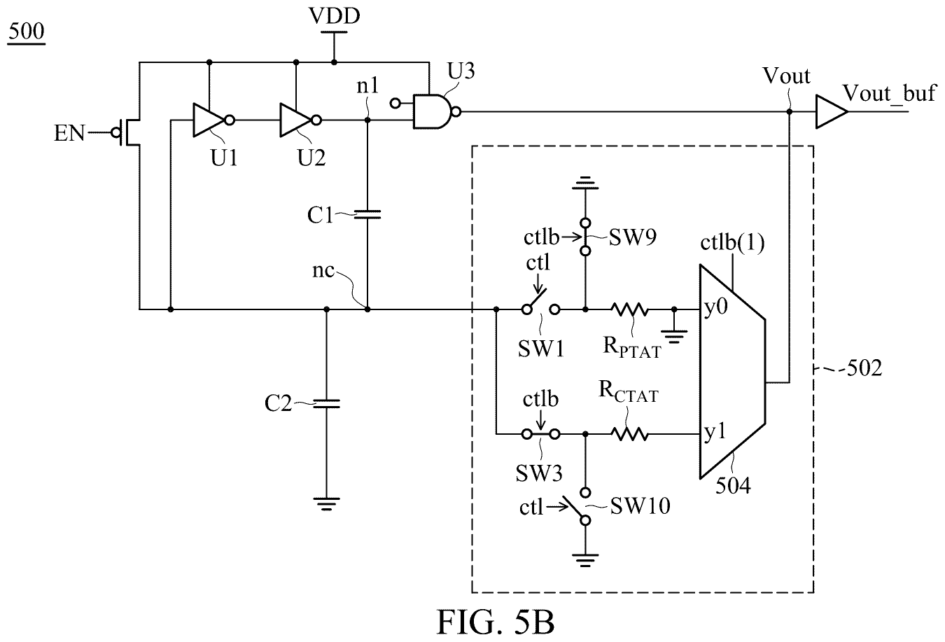

FIG. 5A and FIG. 5B depict a ring oscillator 500 using another temperature-sensitive resistance circuit 502 in accordance with an exemplary embodiment of the disclosure. The temperature-sensitive resistance circuit 502 uses a demultiplexer 504 to replace the switches SW2 and SW4 in the temperature-sensitive resistance circuit 202. Furthermore, instead of using the four switches SW5 to SW8 in the temperature-sensitive resistance circuit 202, the temperature-sensitive resistance circuit 502 uses another two switches SW9 and SW10 to suppress the leakages between the two ends of the disabled resistor (R_{PTAT} or R_{CTAT}).

The demultiplexer 504 has an input terminal receiving the output signal Vout, and represents the output signal Vout at a first output terminal y0 or a second output terminal y1 as controlled by the inverse control signal ctlb. The switch SW9 is controlled by the inverse control signal ctlb. The switch SW10 is controlled by the control signal ctl.

FIG. 5A shows that the temperature-sensitive resistance circuit 502 is switched to the first mode (rm mode) to obtain the oscillation period Period_{PTAT} by the enabled R_{PTAT}. The control signal ctl is 1 and the inverse control signal ctlb is 0. The demultiplexer 504 controlled by the inverse control signal ctlb (0), therefore, represents the output signal Vout at the first output terminal y0. Different from FIG. 2A which form a leakage path between the enabled R_{PTAT} and the output terminal Vout, the demultiplexer 504 blocks the leakage through the path between the enabled R_{PTAT} and the output terminal Vout. Furthermore, the demultiplexer 504 ties the second output terminal y1 to the ground. Because the switch SW10 is closed by the control signal ctl, both of the two ends of the disabled R_{CTAT} are biased at the ground voltage. The leakage through the disabled R_{CTAT} is also suppressed.

FIG. 5B shows that the temperature-sensitive resistance circuit 502 is switched to the second mode (rhr mode) to obtain the oscillation period Period_{CTAT} by the enabled R_{CTAT}. The control signal ctl is 0 and the inverse control signal ctlb is 1. The demultiplexer 504 controlled by the inverse control signal ctlb (1), therefore, represents the output signal Vout at the second output terminal y1. Different from FIG. 2B which form a leakage path between the enabled R_{CTAT} and the output terminal Vout, the demultiplexer 504 blocks the leakage through the path between the enabled R_{CTAT} and the output terminal Vout. Furthermore, the demultiplexer 504 ties the first output terminal y0 to the ground. Because the switch SW9 is closed by the inverse control signal ctlb, both of the two ends of the disabled R_{PTAT} are biased at the ground voltage. The leakage through the disabled R_{PTAT} is also suppressed.

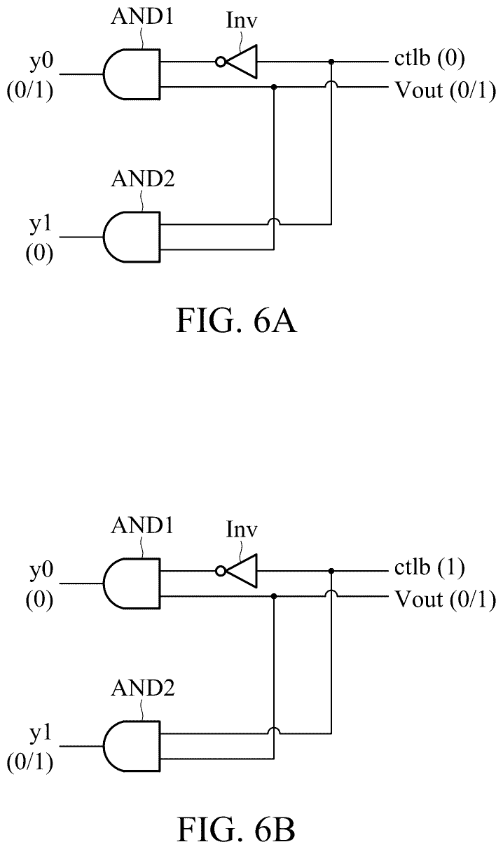

FIG. 6A and FIG. 6B show an example of the demultiplexer 504 in accordance with an exemplary embodiment of the disclosure, which includes one inverter Inv, and two AND gate AND1 and AND2. Through the inverter Inv, the inverse control signal ctlb is inversed and then coupled to the AND gate AND1. Another input terminal of the AND gate AND1 receives the output signal Vout. The second AND gate AND2 receives the inverse control signal ctlb and the output signal Vout. The output terminal of the AND1 and the output terminal of AND2 work as the first output terminal y0 and the second output terminal y1 of the demultiplexer 504, respectively. FIG. 6A shows that when the inverse control signal ctrlb is 0 (referring to FIG. 5A), the output signal Vout is represented at the first output terminal y0 and the second output terminal y1 is tied to 0. Different from a direct connection between y0 and Vout, AND1 blocks the leakage path. FIG. 6B shows that when the inverse control signal ctrlb is 1 (referring to FIG. 5B), the output signal Vout is represented at the second output terminal y1 and the first output terminal y0 is tied to 0. Different from a direct connection between y1 and Vout, AND2 blocks the leakage path.

The specific structure of the demultiplexer 504 may vary. The temperature-sensitive resistance circuit 502 using the demultiplexer 504 may have some modifications.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A thermal sensor, comprising:
a ring oscillator, oscillating based on a resistance-and-capacitance coefficient, wherein the ring oscillator includes a temperature-sensitive resistance circuit, and a resistance factor of the resistance-and-capacitance coefficient depends on the temperature-sensitive resistance circuit;
wherein temperature information, T, is evaluated based on oscillation of the ring oscillator.

2. The thermal sensor as claimed in claim 1, wherein the temperature-sensitive resistance circuit comprises:
a proportional-to-absolute-temperature resistor which corresponds to a positive temperature coefficient.

3. The thermal sensor as claimed in claim 2, wherein the temperature-sensitive resistance circuit further comprises:
a complementary-to-absolute-temperature resistor which corresponds to a negative temperature coefficient, and is operative to remove higher-order non-ideal factors from an evaluated result of the temperature information, T.

4. The thermal sensor as claimed in claim 3, further comprising:
a computing module, switching the temperature-sensitive resistance circuit between a first mode and a second mode;
wherein:
in the first mode, the proportional-to-absolute-temperature resistor is enabled, the complementary-to-absolute-temperature resistor is disabled, and a first oscillation period, Period_{PTAT}, of the ring oscillator is obtained; and
in the second mode, the complementary-to-absolute-temperature resistor is enabled, the proportional-to-absolute-temperature resistor is disabled, and a second oscillation period, Period_{CTAT}, of the ring oscillator is obtained; and
the computing module evaluates the temperature information, T, based on a divided value, Period_{PTAT}/Period_{CTAT}.

5. The thermal sensor as claimed in claim 4, wherein:
the computing module generates a digital code, D, to represent the temperature information, T, where,
$$D = \frac{{Peiord}_{PT AT}}{{Peiord}_{CT AT}} \times {2}^{14} .$$

6. The thermal sensor as claimed in claim 5, wherein:
the computing module calculates an enhanced temperature coefficient, TC_{enhanced}, based on Period_{PTAT}/Period_{CTAT} obtained in several temperatures, and transforms the digital code, D, to the temperature information, T, based on the enhanced temperature coefficient, TC_{enhanced}.

7. The thermal sensor as claimed in claim 6, wherein:
three divided values,
$$\frac{{Peiord}_{PT AT}}{{Peiord}_{CT AT}} @ 125 ° C . , \frac{{Peiord}_{PT AT}}{{Peiord}_{CT AT}} @ - 40 ° C . , and \frac{{Peiord}_{PT AT}}{{Peiord}_{CT AT}} @ 30 ° C . ,$$
are obtained at three different temperatures, 125° C., −40° C., and 30° C.;
the computing module calculates the enhanced temperature coefficient, TC_{enhanced}, by performing the following calculation:
$${TC}_{enhanced} = \frac{\frac{{Peiord}_{PT AT}}{{Peiord}_{CT AT}} \times {2}^{14} @ 125 ° C . - \frac{{Peiord}_{PT AT}}{{Peiord}_{CT AT}} \times {2}^{14} @ - 40 ° C .}{\frac{{Peiord}_{PT AT}}{{Peiord}_{CT AT}} \times {2}^{14} @ 30 ° C . \times ( 125 - ( - 40 ) )} .$$

8. The thermal sensor as claimed in claim 7, wherein:
the computing module evaluates the temperature information, T, by performing the following calculation:
$$T = 30 + \frac{1}{T {C}_{enhanced}} \times ( \frac{D}{D @ 30 ° C .} - 1 ) .$$

9. The thermal sensor as claimed in claim 2, wherein the temperature-sensitive resistance circuit further comprises:
a temperature-insensitive resistor which corresponds to a temperature coefficient of zero, or greater than 0 but smaller than a threshold.

10. The thermal sensor as claimed in claim 1, wherein:
the ring oscillator has a critical node and a first capacitor, wherein the first capacitor is coupled between an input node of a final-stage oscillation unit of the ring oscillator and the critical node;
the ring oscillator further has a second capacitor coupled between the critical node and ground; and
the temperature-sensitive resistance circuit is coupled between an output node of the final-stage oscillation unit and the critical node.

11. The thermal sensor as claimed in claim 10, wherein:
the critical node is an input node of a first-stage oscillation unit of the ring oscillator.

12. The thermal sensor as claimed in claim 10, wherein:
the ring oscillator has a first resistor coupled between the critical node and an input node of a first-stage oscillation unit of the ring oscillator; and
the second capacitor is coupled to the critical node through the first resistor.

13. The thermal sensor as claimed in claim 10, wherein:
the ring oscillator has a second resistor coupled between the critical node and an intermediate node between two oscillation units in front of the final-stage oscillation unit in the ring oscillator.

14. The thermal sensor as claimed in claim 10, wherein:
the ring oscillator has a third resistor coupled between the critical node and an input node of a first-stage oscillation unit of the ring oscillator; and
the second capacitor is coupled to the input node of the first-stage oscillation unit through the third resistor.

15. The thermal sensor as claimed in claim 10, wherein the temperature-sensitive resistance circuit comprises:
a proportional-to-absolute-temperature resistor which corresponds to a positive temperature coefficient, a first switch between the critical node and a first end of the proportional-to-absolute-temperature resistor, and a second switch between a second end of the proportional-to-absolute-temperature resistor and the output node of the final-stage oscillation unit; and
a complementary-to-absolute-temperature resistor which corresponds to a negative temperature coefficient, a third switch between the critical node and a first end of the complementary-to-absolute-temperature resistor, and a fourth switch between a second end of the complementary-to-absolute-temperature resistor and the output node of the final-stage oscillation unit;
wherein the first switch and the second switch are controlled by a control signal, and the third switch and the fourth switch are controlled by an inverse control signal with respect to the control signal.

16. The thermal sensor as claimed in claim 15, wherein the temperature-sensitive resistance circuit comprises:
a fifth switch between the first end of the complementary-to-absolute-temperature resistor and a power terminal of the ring oscillator, and a sixth switch between the second end of the complementary-to-absolute-temperature resistor and the power terminal, wherein the fifth switch and the sixth switch are controlled by the control signal; and
a seventh switch between the first end of the proportional-to-absolute-temperature resistor and the power terminal, and an eighth switch between the second end of the proportional-to-absolute-temperature resistor and the power terminal, wherein the seventh switch and the eighth switch are controlled by the inverse control signal.

17. The thermal sensor as claimed in claim 10, wherein the temperature-sensitive resistance circuit comprises:
a demultiplexer, having an input terminal receiving an output signal from the output node of the final-stage oscillation unit, a first output terminal, and a second output terminal;
a proportional-to-absolute-temperature resistor which corresponds to a positive temperature coefficient, and a first switch arranged between the critical node and a first end of the proportional-to-absolute-temperature resistor, wherein a second end of the proportional-to-absolute-temperature resistor is coupled to the first output terminal of the demultiplexer;
a complementary-to-absolute-temperature resistor which corresponds to a negative temperature coefficient, and a second switch arranged between the critical node and a first end of the complementary-to-absolute-temperature resistor, wherein a second end of the complementary-to-absolute-temperature resistor is coupled to the second output terminal of the demultiplexer;
wherein:
the first switch is controlled by a control signal, and the second switch is controlled by an inverse control signal with respect to the control signal;
when the first switch is turned on, the demultiplexer represents the output signal at the first output terminal of the demultiplexer; and
when the second switch is turned on, the demultiplexer represents the output signal at the second output terminal of the demultiplexer.

18. The thermal sensor as claimed in claim 17, wherein:
when representing the output signal at the first output terminal of the demultiplexer, the demultiplexer ties the second output terminal of the demultiplexer to ground; and
when representing the output signal at the second output terminal of the demultiplexer, the demultiplexer ties the first output terminal of the demultiplexer to the ground.

19. The thermal sensor as claimed in claim 18, wherein the temperature-sensitive resistance circuit further comprises:
a third switch between the first end of the proportional-to-absolute-temperature resistor and the ground, controlled by the inverse control signal; and
a fourth switch between the first end of the complementary-to-absolute-temperature resistor and the ground, controlled by the control signal.

20. The thermal sensor as claimed in claim 18, wherein the demultiplexer comprises:
an inverter, receiving the inverse control signal;
a first AND gate, receiving an output from the inverter and the output signal, and having an output terminal used as the first output terminal of the demultiplexer; and
a second AND gate, receiving the inverse control signal and the output signal, and having an output terminal used as the second output terminal of the demultiplexer.
